(19) United States
(12) Patent Application Publication
(10) Pub. No.: US 2026/0276454 A1
(43) Pub. Date: Sep. 17, 2026

(54) TEMPERATURE MEASUREMENT OF CABLES OF AN ELECTRICAL LINE IN AN UNDERGROUND CONDUIT

(71) Applicant: HYDRO-QUÉBEC, Montréal (CA)

(72) Inventors: Sylvain RIENDEAU, Varennes (CA); Dave LACERTE, Saint-Hyacinthe (CA); François BÉLANGER, Saint-Basile-le-Grand (CA); Louis DUPONT, Sainte-Julie (CA); Pierre GINGRAS, Saint-Bruno (CA)

(21) Appl. No.: 19/166,202

(22) PCT Filed: Mar. 19, 2024
(86) PCT No.: PCT/CA2024/050329

§ 371 Date: Sep. 17, 2025

(30) Foreign Application Priority Data
Mar. 20, 2023 (CA) 3193351

(51) Int. Cl. G01K 1/08; G01K 1/02; G01K 1/024

(52) U.S. Cl. CPC G01K 1/08; G01K 1/024; G01K 1/026; G01K 2215/00

(57) ABSTRACT

A temperature probe with digital sensors distributed in a flexible tube is disclosed. The probe has a tapered tip at one end of the tube to facilitate its insertion into an underground conduit to measure the temperature of a cable twist of a power line in operation in the conduit, leaving only a limited space between the cable twist and an internal surface of the conduit. The number and distribution of sensors are based on a linear distance between two longitudinal peaks of the cable bundle. A telemetry system and a temperature measurement method using the probe are also disclosed.

### FIELD OF THE INVENTION

The invention generally relates to power lines in underground conduits, and more particularly to a temperature probe for measuring the temperature of a twisted cables in a power line in an underground conduit that leaves only a limited space between the twisted cables and an internal surface of the conduit. The invention also relates to a telemetry system and a method of measuring temperature using the temperature probe.

### BACKGROUND

The maximum operating temperature of underground MV (medium voltage) and LV (low voltage) cables is a key factor limiting the transmission capacity of one or more underground power lines. One location where maximum cable temperatures can be reached is in conduits of underground duct banks. Simulation software can be used by a designer (specialist in electrical power transmission and distribution) to estimate the temperature of cables of a line based on various cable arrangements and their position in a duct bank, taking into account the average and maximum historical loads on the line. However, simulations are based on an imprecise estimate of factors that greatly influence the results, such as soil thermal conductivity, groundwater level, etc. Simulations generally include a safety margin and are therefore conservative. The results of the simulations can be ambiguous, i.e., whether loaded lines can carry more current or not. An increase in the load to be transmitted and the inability of adding a new line in an existing duct bank are tigering factors for building new duct banks. However, this generally involves costs of several million dollars and significant delays on the order of years before they can be commissioned and operated.

Some techniques and devices have been proposed in the past for measuring the temperature of an underground power transmission line or the temperature in a conduit containing different types of cables. Patent applications JP2001165781A (Hitachi Cable Ltd), JP2004251672A (Hitachi Cable Ltd), JP2004264090A (Chugoku Electric Power Co Inc, Furukawa Electric Co Ltd), JP2007003516A (Tokyo Electric Power Co Inc), JP2010002281A (Kansai Electric Power Co Inc, J-Power Systems Corp), JPH03107735A, (Tokyo Electric Power Co Inc, Hitachi Cable Ltd, WO2020052984A1 (ABB Schweiz Ag), and patents U.S. Pat. No. 6,811,307 (Draka Comteq BV), U.S. Pat. No. 6,890,095 (MAMAC Systems Inc), U.S. Pat. No. 8,130,101 (Lockheed Martin Corp), and U.S. Pat. No. 8,775,151 (SensorTran Inc) provide examples of techniques and devices in the field, although in general few details are given on their implementation, design, or practical execution.

Known techniques and devices have several shortcomings. For example, the often-proposed use of an optical fiber as a temperature sensor to measure the temperature of a power line involves high installation and measurement equipment costs. In addition, temperature measurement and its location along the optical fiber are imprecise. Generally, the method used involves provoking photon collisions that create an acoustic shock wave causing the fiber to vibrate. The resonant frequency depends on the temperature and the mechanical load on the fiber. When positioning the fiber, a mechanical load on the fiber cannot be avoided. This will induce a relatively significant error in the measurement. As for positional accuracy, it depends on the accuracy of the time measurement. The more accurate the time measurement, the more sensitive and expensive the equipment. In the case of an analog sensor based, for example, on a thermistor or thermocouple, the magnetic and electric fields produced by an operating power line are highly likely to alter the sensor's temperature measurement or the transmission of a measurement signal produced by the sensor. A probe equipped with a single temperature sensor moved to different depths in a conduit near a power line allows only one measurement at a given time, requires on-site handling that may be impossible in a flood-prone structure and in the presence of contaminants or debris, and the accuracy of the temperature measurement provided by the sensor is not guaranteed, as the distance between the cable and the sensor is unknown. The manufacture of a cable or the construction of a conduit incorporating one or more temperature sensors, prior to installation or operation, also involves significant costs and entails installation and maintenance constraints, which may further complicate the working procedures of those involved. Methods requiring measurement in an empty conduit adjacent to that of a power line are not useful when no empty conduit is available and are generally less accurate due to additional variable parameters in calculating the temperature of the line versus that in the empty conduit. Finally, known devices are not suitable for easy insertion to a depth of several meters into an underground conduit housing an electrical line that is not longitudinally smooth, for example, a line formed of twisted cables as is generally the case for underground MV and LV lines, in addition to ensuring thermal contact with the insulation of at least one of the cables in order to obtain accurate temperature measurements.

### SUMMARY

One object of the present invention is to provide a temperature probe for a twisted cable of an electrical line operating in an underground conduit, leaving only a limited space between the twisted cable and an internal surface of the conduit, which is easy to insert several meters into the conduit while the cables are energized (powered) and under load (carrying current), which allows the temperature to be measured at any time and simultaneously at several depths in the conduit, which is not very sensitive to a magnetic or electric field produced by the cables, and which allows the temperature profile of the cables and their cores in the conduit to be determined accurately.

A secondary objective of the invention is to provide a temperature measurement probe that allows the precise real-time temperature of the most heavily used cables in underground conduits to be determined to optimize the operation of the underground electrical network at the thermal capacity limit of the cables and to avoid or postpone the construction of new lines and associated underground structures.

Another subsidiary object of the invention is to provide a temperature probe that is robust and can be waterproofed so that it can be submerged continuously or occasionally.

According to one embodiment of the present invention, a temperature probe is proposed for measuring the temperature of twisted cables of an electrical line in operation in an underground conduit leaving only a limited space between the twisted cables and an internal surface of the conduit, the temperature probe comprising:
an electrically insulating flexible tube, the flexible tube having first and second opposite ends and an outer diameter less than said limited space, the first end being adapted to be inserted into the conduit from an opening of the conduit to a depth within the conduit, the second end being adapted to remain accessible near the opening of the conduit when the first end is at said depth within the conduit;
an electrically insulating tapered tip sealingly attached to the first end of the flexible tube and configured to facilitate insertion of the flexible tube into the restricted space along the twisted cables in the conduit;
an array of digital temperature sensors housed and distributed longitudinally within the flexible tube, the number and distribution of the digital sensors being based on a linear distance between two longitudinal peaks of the twisted cables; and
a connection assembly connecting the digital sensors, the connection assembly having a power supply circuit for supplying power to the digital sensors, and a communication circuit extending from the second end of the flexible tube for externally transmitting digital signals indicative of the temperatures measured by the digital sensors.

According to another embodiment of the invention, a system is provided for remotely measuring the temperature of an accessible section of an electrical line in operation in an underground conduit, the remote measurement system comprising:
a temperature probe with digital sensors distributed in a flexible tube running along a length of the section of the power line in the underground conduit;
a power supply assembly connected to an electrical power source; and
an acquisition unit having an input connected to the power supply assembly for receiving electrical power, a connection port connected to the temperature probe for electrically powering the digital sensors and receiving digital temperature signals measured by the digital sensors, and a telecommunications device configured to transmit to a remote site of the underground conduit temperature measurement signals derived from the digital temperature signals received by the acquisition unit.

According to another embodiment of the invention, a method is proposed for measuring the temperature of an accessible section of an electrical line in operation in an underground conduit, the method comprising the steps of:
inserting a temperature probe with distributed digital sensors into a flexible tube so that the flexible tube runs along a length of the section of the electrical line in the underground conduit;
providing a power supply assembly connected to an electrical power source;
electrically powering the digital sensors of the temperature probe through an acquisition unit receiving electrical power from the power supply assembly;
receiving, via the acquisition unit, digital temperature signals measured by the digital sensors;
transmitting, via a telecommunications device, temperature measurement signals derived from the digital temperature signals received by the acquisition unit;
receiving, at a site remote from the underground conduit, the temperature measurement signals; and
processing, at the remote site, the digital temperature signals to determine a temperature of the electrical line based on at least one of the temperatures measured by the digital sensors, including the measured temperature that is the highest.

### BRIEF DESCRIPTION OF THE DRAWINGS

A detailed description of the preferred embodiments of the invention will be given below with reference to the following drawings:

FIG. 1 is a schematic cross-sectional view of an underground duct bank showing a temperature probe inserted into a conduit of a power line, an acquisition unit connected to the probe, and a telecommunication system for data produced by the acquisition unit, according to one embodiment of the invention.

FIG. 2 is a schematic view of a temperature measurement probe according to one embodiment of the invention.

FIG. 3 is a schematic cross-sectional view of a temperature measuring probe according to one embodiment of the invention.

FIG. 4 is a partial schematic view of a connection assembly of a digital temperature sensor in the temperature probe according to one embodiment of the invention.

FIG. 5 is a schematic cross-sectional view of a temperature probe according to another embodiment of the invention.

FIGS. 6A, 6B, and 6C are schematic perspective and side views of a tapered tip of a temperature probe according to one embodiment of the invention.

FIG. 6D is a schematic view illustrating a shape of a tapered tip of a temperature probe according to one embodiment of the invention.

FIG. 7 is a schematic longitudinal section of a temperature probe running along an MT line in a conduit according to one embodiment of the invention.

FIG. 8 is a schematic cross-sectional view of a temperature probe of an MT line in a conduit according to an embodiment of the invention.

FIG. 9 is a graph illustrating a profile of temperature measurements taken by a temperature probe according to the invention.

### DETAILED DESCRIPTION OF THE PREFERRED IMPLEMENTATIONS

In this disclosure, unless otherwise specified or the context implies a different interpretation, the expression “corresponding to” or “corresponding with” should be understood to mean that a substantial correspondence, with some leeway, is possible. Similarly, the determiner “one” should not be interpreted restrictively if the context permits, so that it can mean “at least one” or “one or more.”

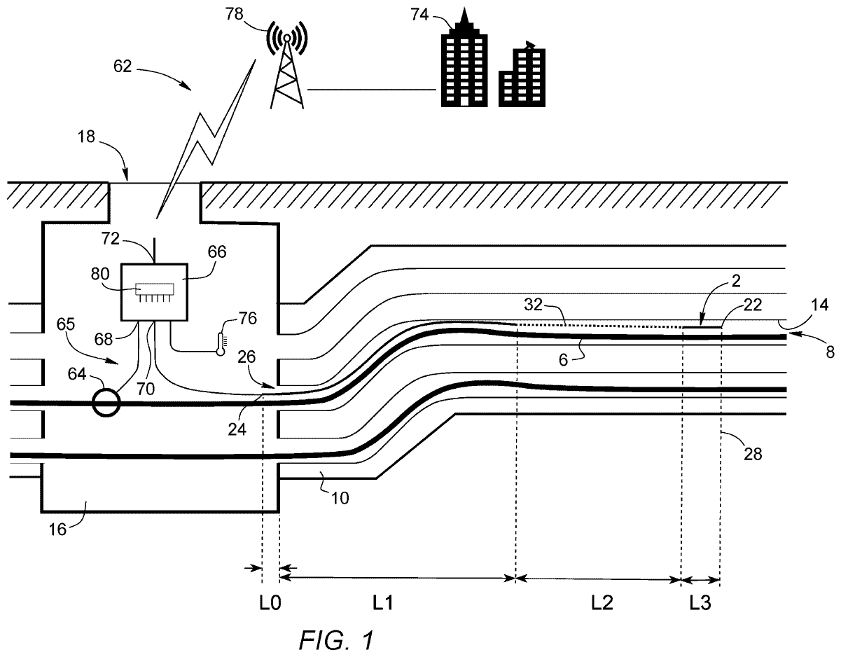

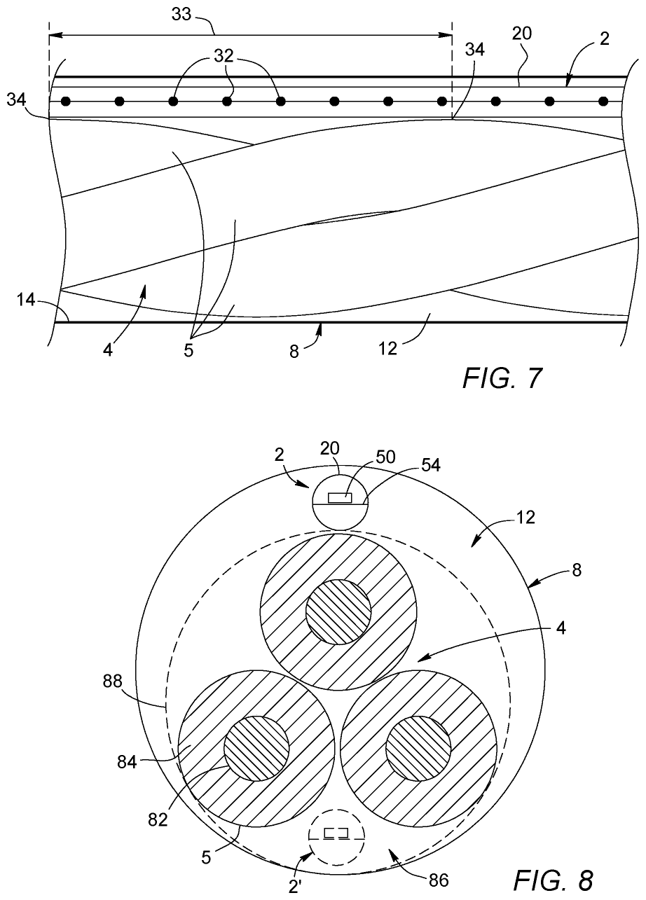

With reference to FIG. 1, a temperature probe 2 according to the invention is illustrated in an operational position. The temperature probe 2 is designed to measure a temperature of a twist 4 of cables 5 (illustrated e.g. in FIG. 7) of an electrical line 6 in operation in an underground conduit 8 leaving only a limited space 12 (illustrated e.g. in FIG. 8) between the twist 4 of cables 5 and an internal surface 14 of the conduit 8. The conduit 8 may be a conduit of an underground duct bank 10, which is generally made of concrete and is connected to a chamber 16 with an access shaft 18 on the surface or otherwise accessible, allowing access to the line 6 or, more generally, a set of underground power lines, in particular lines of an underground MV or LV distribution network (and other equipment that may be located in chamber 16). Such a chamber 16 is used in particular to make connections (joints or branches) between several sections of underground cables. The temperature in an underground conduit 8 of a duct bank 10 is usually stable beyond a depth of 3 to 4m in the conduit 8 and is no longer affected by the temperature of the underground structure forming the chamber 16. The configuration and thermal properties of the soil are generally homogeneous over the length of the duct bank 10.

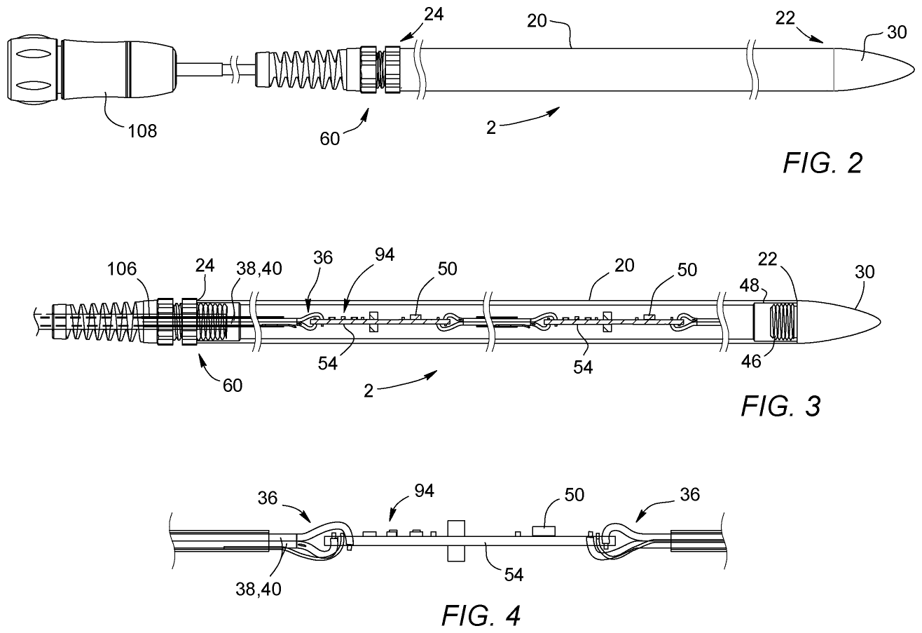

With reference to FIG. 2, the temperature probe 2 comprises an electrically insulating flexible tube 20. The flexible tube 20 a has first and second opposite ends 22, 24 and an outer diameter smaller than the restricted space 12 (illustrated e.g. in FIG. 8).

Referring again to FIG. 1, the first end 22 is adapted to be inserted into the conduit 8 from an opening 26 in the conduit 8 to a depth 28 in the conduit 8. The second end 24 is adapted to remain accessible near the opening 26 in the conduit 8 when the first end 22 is at the depth 28 in the conduit 8.

Referring again to FIG. 2, the temperature probe 2 includes an electrically insulating tapered tip 30 sealed to the first end 22 of the flexible tube 20 and configured to facilitate insertion of the flexible tube 20 into the restricted space 12 along the twist 4 of cables 5 in the conduit 8, as illustrated e.g. in FIG. 7.

According to an embodiment, the flexible tube 20 and the tapered tip 30 are made of materials that can withstand temperatures of at least 125° C. without altering their shape or physical properties. Suitable materials are PVDF (polyvinylidene fluoride) or PTFE (polytetrafluoroethylene), which provide electrical insulation properties, sufficient rigidity at low and high temperatures, and a minimal coefficient of friction to facilitate insertion of the temperature probe 2 into the conduit 8 of the duct bank 10 (illustrated e.g. in FIG. 1). Such materials have low thermal inertia, which allows them to quickly follow the local temperature during rapid changes in the immediate environment, and are resistant to chemicals, meaning they do not degrade when in contact with oils or de-icing salt that may be present in chamber 16 or conduit 8 (illustrated e.g. in FIG. 1). Other materials may be suitable, particularly if they are electrically insulating and have flexibility and/or semi-rigidity characteristics that allow the flexible tube 20 to fit into the confined space 12 while preventing it from becoming clogged when inserted into the conduit 8 (illustrated, for example, in FIG. 1). A silicone-based adhesive may be used between the flexible tube 20 and the tapered tip 30 to ensure a tight seal. A semi-transparent PVDF tube is particularly suitable for forming the flexible tube 20.

With reference to FIGS. 6A, 6B, and 6C, in an embodiment, the tapered tip 30 has a base 42 having a diameter corresponding to the outer diameter of the flexible tube 20 (shown e.g. in FIG. 3) such that the base 42 of the tapered tip and the first end 22 (shown e.g. in FIG. 3) of the flexible tube 20 have a smooth external interface when the tapered tip 30 is in a sealing position with the first end 22 of the flexible tube 20. According to an embodiment, the tapered tip 30 has a rounded edge 52 on a side opposite the base 42, and a parabolic circumference 54 extending between the rounded edge 52 and the base 42. The tapered tip 30 may have a fastening element 46 projecting from the base 42 and fitting into an axial hole 48 at the first end 22 of the flexible tube 20 (illustrated e.g. in FIG. 3) to secure the tapered tip 30 in a sealed manner to the flexible tube 20. The fastening element 46 and the axial hole 48 may advantageously comprise complementary threads so that the tapered tip 30 screws into the first end 22 of the flexible tube 20. The complementary threads may be defined according to the American NPT (“National Pipe Thread”) standard to ensure the tightness of the fastening. Other fastening arrangements may be used to fasten the tapered tip 30 to the first end 22 of the flexible tube 20, so that the tapered tip 30 is detachable or non-detachable from the flexible tube 20.

With reference to FIG. 6D, the shape of the tapered tip 30 can be characterized by a length L and a diameter D, the outer surface 54 of which is formed by rotation around a central axis 94 of the tapered tip 30. The outer surface 54 passes through a peak 96 of the tip located on the central axis 94 at a distance L from a center 98 of the base 42 of the tapered tip 30, where each point 100, 102 in×104 on the outer surface 54 extending away from the peak 96 towards the base 42 on a circumference of the base 42 of the tapered tip 30 has an increasingly negative slope (derived from the curve of the surface 54), starting from a zero slope at the peak 96 towards a slope that ideally tends towards negative infinity at the base 42 of the tapered tip 30 for continuity of shape with the flexible tube 20 (illustrated e.g. in FIG. 2) preferably also of diameter D. Typical, but not limiting, dimensions of the tapered tip 30 are a length L of 30 mm and a diameter D of 15.88 mm, under a curve profile of the surface 54 that can be considered parabolic.

With reference to FIG. 3, the temperature probe 2 comprises an array of digital temperature sensors 50 housed and distributed longitudinally in the flexible tube 20. The number and distribution of the digital temperature sensors 50 depend on a linear distance 33 between two longitudinal peaks 34 of the twisted pair 4 of cables 5, as illustrated in FIG. 7. A digital sensor model particularly suitable for the temperature probe 2 is the TMP107 sensor manufactured by Texas Instruments. A chain comprising up to 32 individually addressable sensors connected in cascade, capable of communicating over a distance of 300m, can be formed with such a sensor model. In addition, this sensor model has low power consumption and can be powered only when reading the temperature. Communication over a 1-Wire serial link ranging from 4.8 kbaud to 115.4 kbaud allows this type of sensor to be interfaced using a UART (Universal Asynchronous Receiver Transmitter) controller and an open collector output with only 3 wires. The use of digital sensors 50 allows digital reading and conversion of data at the reading points, which avoids transmitting analog signals over several meters in a noisy electromagnetic environment. Other sensor models may also be suitable, such as the LMT01-LR sensor also manufactured by Texas Instruments. Digital sensors such as the TMP107 and LMT01-LR are minimally affected by strong currents that generate magnetic or electric fields and can therefore be installed within range of MV cables that can carry hundreds or even thousands of amps without being disturbed by their magnetic field.

With reference to FIG. 4, a connection assembly 36 is connected to the digital sensors 50. The connection assembly 36 includes a power supply circuit 38 for supplying power to the digital sensors 50, and a communication circuit 40 extending from the second end 24 of the flexible tube 20 (illustrated e.g. in FIG. 3) to externally transmit digital signals indicative of the temperatures measured by the digital sensors 50. The power supply 38 and communication 40 circuits of the connection assembly 36 may advantageously be implemented by twisted conductors with shielding between the digital sensors 50 for shielding from magnetic and electric fields. Depending on the make and model, the digital sensors 50 may be operatively connected in cascade to each other by the connection assembly 36.

Referring again to FIG. 3, in an embodiment, the digital sensor array 50 comprises printed circuit boards 54 on which the digital sensors 50 are respectively mounted and are operatively connected. The printed circuit boards 54 have dimensions that allow clearance relative to an internal diameter of the flexible tube 20 while supporting the digital sensors 50 at or near an axial center of the flexible tube 20 by contact with an internal surface of the flexible tube 20 as illustrated in FIG. 8. Power and signal conditioning filters 94 formed e.g. by capacitors and resistors may be mounted on the printed circuit boards 54. An alignment of the capacitors and resistors along the printed circuit boards 54 may be advantageous to decrease physical stress applied to these components. Extending the copper of the solder mask beyond the component footprints can help ensure that the copper does not peel away from an inner insulating layer of the printed circuit boards 54 (usually polyimide).

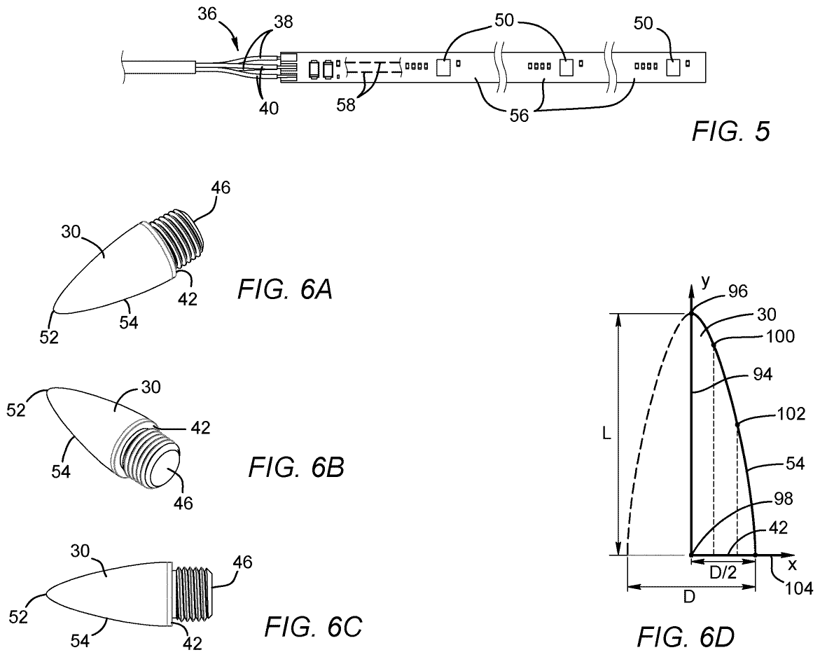

With reference to FIG. 5, according to an embodiment, the printed circuit boards 54 may advantageously be flexible boards arranged end-to-end, for example by being soldered together to form a continuous strip of printed circuits 56 extending over a length exceeding the distance between a first and a last of the digital sensors 50, simplifying precise positioning of the digital sensors 50 in the flexible tube 20 along the temperature probe 2 (illustrated, for example, in FIG. 3). The power supply 38 and communication 40 circuits of the connection assembly 36 can then be implemented by circuits 58 formed on (e.g., under) and interconnected between the printed circuit boards 54 by board end contacts (“fingers”) (not shown). The ground conductors of the power supply 38 and communication 40 circuits may be twisted between the digital sensors 50 to reduce the influence of a magnetic field while avoiding, as much as possible, a copper surface affecting the flexibility of the printed circuit strip 56 between the digital sensors 50 or acting as a thermal bridge. The printed circuit boards may also be formed by a single elongated flexible printed circuit board.

With reference again to FIG. 3, according to an embodiment, the temperature probe 2 further comprises an outlet fitting 60 sealed to the second end 24 of the flexible tube 20 so that the temperature probe 2 is submersible. The power supply circuit 38 and the communication circuit 40 then pass through the outlet fitting 60 in a sealed manner. The outlet fitting 60 may advantageously be formed by a cable gland and silicone to form a sealed joint with a cable 106 containing the conductors of circuits 38 and 40 (e.g., power supply, power supply ground, communication+, communication-ground). The cable 106 may advantageously be provided with a connector 108 (shown in FIG. 2) such as a corrosion-resistant watertight bayonet connector that can be submerged to a depth of 1 bar (10.1 m). The watertight seal can be used to set the positions of the power supply circuits 38 and communication circuits 40 in the flexible tube 20 and to control the position of the digital sensors 50 inside the flexible tube 20. Since the circuits 38, 40, and digital sensors 50 are not attached to the inner wall of the flexible tube 20, there are no mechanical stresses on them and flexibility along the entire length of the flexible tube 20 is not impeded. The flexible tube 20 may be filled with a component conducive to heat transfer that does not significantly increase the thermal mass around the digital sensors 50 or their response time during a change in temperature of line 6 or the ambient environment in conduit 8 (illustrated, for example, in FIG. 1). The power supply 38 and communication 40 circuits may advantageously be coated with a protective layer (“conformal coating”) to protect them from possible condensation of moisture trapped in the temperature probe 2 during its assembly. The cable 106 may contain aluminum or copper metal shielding for protection against electric fields and electrostatic discharge, and its sheath may be made of FEP (fluoroethylene propylene) or E-CTFE (ethylene chlorotrifluoroethylene) for protection against oils, water, and UV rays. An FEP cable, capable of carrying a signal of e.g. 88 kHz, is particularly suitable for forming cable 106.

Referring again to FIG. 8, conduit 8 is not necessarily straight along its entire length (as illustrated, for example, in FIG. 1) and twist 4 rests in conduit 8, taking a minimal bend at each change of direction of conduit 8. To take into account restrictions caused by the potential presence of debris or changes in direction of the conduit 8, the temperature probe 2 must in such cases be able to slip into the space 12 of an area 88 delimited by the twist 4, as well as into free spaces 86, as illustrated, for example, by a possible position of the temperature probe 2′. These spaces 12, 86 determine a maximum diameter of the flexible tube 20 of the temperature probe 2. For example, for a duct 8 with an inner diameter of 11.43 cm (4.5 in), the outer diameter of the flexible tube may be 1.59 cm (0.625 in).

According to a possible embodiment, the stiffness of the material or materials used for the flexible tube 20 must be sufficiently high to prevent jamming and deformation of the temperature probe 2 during its insertion into the conduit 8. The radius of curvature of the flexible tube 20 should be greater than the internal radii of curvature of the conduit 8 and less than the radii of curvature of bends in the conduit 8. The flexible tube 20 must not collapse under the pressure of any liquid that may be present in the conduit 8 and chamber 16 (shown in FIG. 1). Conduits 8 of duct bank 10 may be buried to a depth of 5m and chamber 16 (as illustrated e.g. in FIG. 1) may be flooded to ground level so as to exert a pressure of 7.3 psi. A flexible tube 20 made, for example, of PTFE has a Durometer hardness of 75D, a bend radius of 6.35 cm (2.5 in.), and is resistant to a pressure of 140 psi. The thickness of the flexible tube 20 may also be considered to suit the required characteristics, depending on the material or materials of which it is made.

With reference again FIG. 1, the temperature probe 2 according to the invention can advantageously be integrated into a temperature telemetry system 62 for an accessible section of the power line 6 in operation in the underground conduit 8 of the underground duct bank 10. In the case illustrated in FIG. 1, the second end 24 of the temperature probe 2 protrudes from the conduit 8 by a distance L0 (e.g. 15 cm) so that the temperature probe 2 can be manipulated once it has been inserted into the conduit 8. L1 represents a distance from which a temperature at the insertion point of the temperature probe 2, such as the temperature at the opening 26 of the conduit 8, no longer affects the temperature in the conduit 8 and from which the conduit 8 is exposed to a stable environment and represents the worst operating condition of the line 6. A duct bank 10 is usually buried approximately 0.75 m in the ground. L2 represents a minimum/optimal interval for taking temperature measurements in conduit 8. L2 also represents a length of temperature probe 2 where digital sensors 50 can be distributed in flexible tube 20 (illustrated e.g. in FIG. 2) running along a length of the section of power line 6 in conduit 8. L2 may correspond to approximately 1.5 times the distance 33 between two longitudinal peaks 34 of the twist 4 of cables 5 as illustrated in FIG. 7, for example approximately 0.9 m for a typical MT cable twist. L3 represents a length of the temperature probe 2 that may be without sensors, terminated by the tapered tip 30 (illustrated e.g. in FIG. 2). The length L3 may serve to stabilize the portion L2 of the temperature probe 2 in the conduit 8.

The telemetry system 62 includes a power supply assembly 65 connected to a power source such as, for example, the power line 6 itself. In this case, the power supply assembly 65 may include a coupler (or converter) 64 configured to generate power from the power line 6. The coupler 64 may be of the inductive type or of the capacitive type. The electrical power may also come from another source, such as a conventional low-voltage power source (not shown) if present, or from an electrical accumulator (battery, supercapacitor, capacitor, etc.) (not shown) having sufficient capacity for the intended application.

An acquisition unit 66 is installed in the chamber 16. The acquisition unit 66 a has an input 68 connected to the inductive coupler 64 to receive the supplied power, a connection port 70 connected to the temperature probe 2 to electrically power the digital sensors 50 and receive the digital temperature signals measured by the digital sensors 50, and a telecommunications device 72 configured to transmit to a site 74 remote from the underground duct bank 10 temperature measurement signals derived from the digital temperature signals received by the acquisition unit 66. The signals may be transmitted, for example, via a wireless network 78 or otherwise. In the case of a wireless network 78 such as a cellular network, the system according to the invention may advantageously use a wireless telecommunications system such as that disclosed in U.S. Pat. No. 11,171,402 (Riendeau et al.), the entirety of which is incorporated herein by reference. The acquisition unit 66 may include a microcontroller 80 configured to take readings from all digital sensors 50 at fixed intervals, for example, one minute. The interval between readings may be determined based on expected variations in load, the thermal mass of line 6, and adjusted based on the amount of energy available to power the system. The interval may also be determined based on a history of variations in temperature measurements or by simulation, taking into account the thermal masses and maximum variations in the load on line 6. The interval between readings may also be adjusted dynamically based on a variation in the load on line 6 that can be measured locally, for example by the inductive coupler 64.

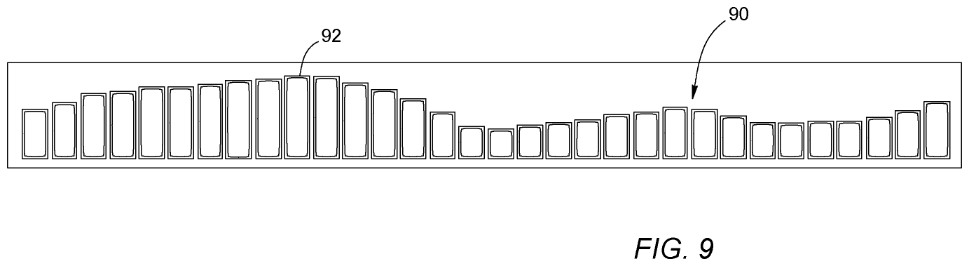

With reference to FIG. 9, an example of displaying temperatures 90 measured by digital sensors 50 of temperature probe 2 (illustrated e.g. in FIG. 1) is shown. In the example, the digital sensors are spaced apart from each other, ranging from 5 m (left measurement) to 4.3 m (right measurement) of depths in the conduit 8 (illustrated e.g. in FIG. 1). A maximum temperature 92, for example, of 35.04° C. is measured by the digital sensor 50 located at a depth of 4.8 m in the conduit 8 (illustrated e.g. in FIG. 1).

Referring again to FIG. 1, according to an embodiment, a sensor 76 for measuring the ambient temperature of the underground duct bank 10 is connected to the acquisition unit 66. The acquisition unit 66 is configured to transmit to the remote site 74, via the telecommunications device 72, a temperature measurement signal indicative of the ambient temperature measured by the sensor 76. The sensor 76 may be installed in the chamber 16, inserted into the ground or the duct bank 10 near the chamber 16, or inserted into a free conduit 8 of the duct bank 10. The sensor 76 may be implemented by a temperature probe according to the invention, in particular for insertion into the ground so as to be able to provide temperature measurements at different depths of insertion into the ground.

The acquisition unit 66 or the temperature probe 2 may be configured to preprocess the digital temperature signals before transmitting the temperature measurement signals via the telecommunications device 72. In the case of the temperature probe 2, preprocessing of the digital signals can be performed in the digital sensors 50 themselves or by a preprocessing circuit (not shown) located, for example, in the flexible tube 20 near the second end 24. In the case of the acquisition unit 66, preprocessing of the signals may be performed by the microcontroller 80, which may also be used to control various functions of the acquisition unit 66. The microcontroller 80 may be configured, for example, so that all readings from the digital sensors 50 are transmitted for remote processing, or only a subset of readings or processed values (e.g., minimum and maximum). An average value and a standard deviation of the measurements may also be transmitted. In addition to a temperature value, position data for the digital sensor 50 in the chain may also be used during local processing by the acquisition unit 66 or remote processing 74.

According to an embodiment, the acquisition unit 66 has several connection ports 70 so that other electrical lines 6 in other conduits 8 and other temperature probes 2 can be managed by the acquisition unit 66 of the telemetry system 62.

According to an embodiment, the invention can be implemented and operated as follows. The temperature probe 2 with digital sensors 50 distributed throughout the flexible tube 20 (illustrated e.g. in FIG. 2) is inserted so that the flexible tube 20 runs along a length (e.g. L2) of an accessible section of the power line 6 in the conduit 8 of the underground duct bank 10. Power for the operation of the system is provided by the power supply assembly 65 connected to the power source, e.g. the power line 6 via the coupler 64 (or otherwise another power source if required). The digital sensors 50 of the temperature probe 2 are electrically powered by the acquisition unit 66 receiving the power supplied by the power supply assembly 65. The acquisition unit 66 receives the digital temperature signals measured by the digital sensors 50. Temperature measurement signals derived from the digital temperature signals received by the acquisition unit 66 are transmitted by the telecommunications device 72 to be received and processed at the site 74 remote from the conduit 8 of the underground duct bank 10 in order to determine the temperature of the electrical line 6 according to a highest one of the temperatures measured by the digital sensors 50.

Referring again to FIG. 8, a main source of heat in conduit 8 comes from the RI₂ losses of the conductors/cores 82 of cables 5 of twist 4. The highest temperature is located on the surface of each core 82. It is at this location that the dielectric insulator 84 is exposed to the highest temperature. The temperature of the dielectric insulation 84 of each cable 5 must not exceed the operating limits to avoid deteriorating its mechanical and insulating properties. A twist 4 of cables 5 in a three-phase circuit is composed of 3 identical cables 5 in contact (twisted) along their length. The load current of each cable 5 in a three-phase circuit is normally balanced (identical). As any load imbalance between the cables 5 is insignificant, it can be assumed that the temperature of the core 82 of each cable 5 is very similar. It is therefore sufficient to evaluate the temperature of the core 82 of a single cable 5.

Signal processing may thus advantageously include an estimation of a temperature T_{core} of the core 82 of a cable 5 of the power line 6 (illustrated e.g. in FIG. 1). The estimation of the temperature T_{core} may be determined by different processing modes.

During operation, it can be difficult to estimate the temperature T_{core} solely based on the load current and the geometry of the duct bank 10 without making significant approximations about the thermal properties of the surrounding soil and the level of the water table, which varies according to various environmental factors. Simulation programs use coefficients with significant safety margins that do not take into account the specific characteristics of each installation, hence the importance of continuous measurements to optimize the transit capacity of cables 5.

The insertion depth of the temperature probe 2 into the duct bank 10, at which point the temperature in chamber 16 (illustrated e.g. in FIG. 1) is unlikely to have any influence or be a dominant factor on the temperature inside the conduit 8, may be approximately 3.5 m. Beyond this depth, the insertion depth of the temperature probe 2 is no longer a dominant factor compared to the distances between the digital sensors 50 and the twist 4 of cables 5. One of the difficulties that the invention solves is measuring a temperature at the surface of a cable 5 at such a depth in a conduit 8 in the presence of a twist 4 of cables 5 in operation (under load). The distance between a digital sensor 50 and the surface of the cable 5 introduces a thermal resistance proportional to this distance. For a given distance, the thermal resistance between the digital sensor 50 and the surface of the cable 5 may vary depending on the medium present in the conduit 8, for example air or a liquid such as water. The thermal resistance for air is around 41.7 K·m/W, while that for water is around 1.7 K·m/W. A chain of digital sensors 50, spaced uniformly or not and in sufficient number in the temperature probe 2, makes it possible to obtain at least one temperature reading at a minimum distance from the surface of a cable 5.

Physical contact between the temperature probe 2 and one of the cables 5 of the twist 4, where one of the digital sensors 50 is located, around depth 28, is likely to provide the best result. Table 1 below gives an example of linear distances (or “periods”) 33 between two longitudinal peaks 34 (shown in FIG. 7) of a twist 4 of cables 5 according to different models of common underground MT cables.

TABLE 1

| Cable model | Linear distance of the strand |
|---|---|
| 750 MCM | 60 cm |
| 500 MCM | 50 cm |
| 500 MCM sheathed | 56 cm |
| 350 MCM copper | 40 cm |
| 3/0 AWG | 40 cm |
| 3/0 AWG sheathed | 55 cm |

According to a suitable embodiment, the flexible tube 20 has minimum length defined by a first section (L1 illustrated in FIG. 1) of the flexible tube 20 corresponding to a depth in the conduit 8 from which a temperature near the opening 26 of the conduit 8 no longer has an effect on a temperature in the conduit 8, plus a second section (L2 illustrated in FIG. 1) of the flexible tube 20 corresponding to one and a half times the linear distance 33 (illustrated in FIG. 7). The digital sensors 50 are distributed throughout the second section of the flexible tube 20. The number and distribution of the digital sensors 50 are defined by a spacing between each digital sensor 50 in the second section of the flexible tube 20. The spacing between each digital sensor 50 may vary as desired.

Considering, on the one hand, a temperature probe 2 juxtaposed on a twist 4 of three-phase MT cables 5, which periodically comes into contact with the twist 4 at an interval varying between 40 cm and 60 cm (depending on the specifications of the cables 5), and on the other hand, a resolution and accuracy of the digital sensors 50 as well as a desired measurement accuracy, then a preferred mode consists of a minimum use of 10 digital sensors 50 spaced 10 cm apart from each other. The digital sensors 50 are thus distributed over one and a half periods of the twist 4 between 3.5 m and 4.4 m of insertion depth into the duct bank 10. This design ensures a relative difference between a temperature measurement and that at the surface of a cable 5 of less than 0.2° C., i.e., a difference less than the accuracy of the digital sensors 50 when TMP107 sensors are used, which have an accuracy of +0.4° C. over their operating range for a resolution of +0.015° C.

According to a processing method #1,in steady state, i.e., under stable load and ambient conditions, the temperature T_{Core} can be estimated using the equation

$${T}_{Core} = {T}_{Ambient} + {K}_{Surface} ( {T}_{Surface} - {T}_{Ambient} )$$

where T_{Ambient} is a temperature measured by temperature sensor 76 located in an environment adjacent to conduit 8 of underground duct bank 10, and K_{Surface} is a predetermined coefficient of temperature variation T_{Core} of the core 82 of cable 5 relative to a temperature T_{Surface} at a surface of the cable 5 as measured by the temperature probe 2. The value of K_{Surface} can be determined by finite elements from a geometry of the twist 4 in the conduit 8 and the thermal properties of the materials of the cables 5. This value can also be determined in other ways, such as by laboratory tests. A value of K_{(Surface)} for typical underground MV cables is, for example, 1.147. Since the digital sensor 50 of the temperature probe 2 that is closest to one of the cables 5 in the twist will provide the highest temperature reading, in the simplest case, this temperature is used for T_{Surface}. In this processing method, the distance between the digital sensor 50 measuring the highest temperature and the surface of cable 5, as well as the equivalent thermal resistance, are considered negligible.

According to a processing method #2,assuming that the temperature probe 2 is straight and that it is in contact with the twist 4 at each peak 34 as illustrated in FIG. 7, the maximum temperature measured by one of the digital sensors 50 corresponds to a minimum distance dₘᵢₙ between the digital sensor 50 in question and the surface of one of the cables 5 (e.g., at a point of contact between the temperature probe 2 and the twist 4), while the minimum temperature measured by one of the digital sensors 50 corresponds to a maximum distance dₘₐₓ between the digital sensor 50 in question and the surface of one of the cables 5. A possible improvement for estimating T core consists of using the difference between the minimum and maximum temperatures and the minimum dₘᵢₙ and maximum dₘₐₓ distances (values known by geometry), according to the equation

$${T}_{core} = {T}_{ambient} + {K}_{d} ( {T}_{d} - {T}_{ambient} )$$

where K_{d} is a coefficient determined based on the geometry of the twist 4, and T_{d} is the difference between the maximum and minimum temperatures measured by the digital sensors 50. The applicable coefficient K_{d} can be determined by finite elements for dₘᵢₙ≤d≤dₘₐₓ. From two temperature readings Tᵢ and Tⱼ taken at sensor-to-surface distances of a cable 5 where i and j are known and for which the coefficients Kᵢ and Kⱼ have been evaluated (e.g. by finite elements) according to an anticipated medium between the sensor 50 and the surface of cable 5, it is possible to estimate T_{Ambient} and T_{Core} as follows:

$${K}_{i} ( {T}_{i} - {T}_{Ambient} ) = {K}_{j} ( {T}_{j} - {T}_{Ambient} )$$

$${T}_{Ambient} = \frac{{K}_{i} {T}_{i} - {K}_{j} {T}_{j}}{{K}_{i} - {K}_{j}}$$

$${T}_{Core} = \frac{{K}_{i} {T}_{i} - {K}_{j} {T}_{j}}{{K}_{i} - {K}_{j}} + {K}_{j} ( {T}_{i} - \frac{{K}_{i} {T}_{i} - {K}_{j} {T}_{j}}{{K}_{i} - {K}_{j}} )$$

$${T}_{Core} = {K}_{i} {T}_{i} + ( 1 - {K}_{i} ) ( \frac{{K}_{i} {T}_{i} - {K}_{j} {T}_{j}}{{K}_{i} - {K}_{j}} )$$

where i and j correspond to the distances dₘᵢₙ and dₘₐₓ and the temperatures Tᵢ and Tⱼ obtained from the readings of the digital sensors 50 in the temperature probe 2.

According to a processing method #3,with two minimum or maximum temperature readings and a reciprocal minimum or maximum temperature, and knowing the linear distances in conduit 8 between digital sensors 50, it is possible to correct a deviation of flexible tube 30 of temperature probe 2 or twist 4 in conduit 8 (sensor-surface distance) by establishing a relationship between a linear distance corresponding to the minimum, maximum, and/or maximum-minimum readings and an expected distance between two peaks 34 of the twist 4 of cables 5 (illustrated, for example, in FIG. 7). The K factors corresponding to a shape of the temperature probe 2 (corrected sensor-surface distances) can then be used to apply processing method #2.

According to a processing method #4, the temperature readings from temperature probe 2 can be interpolated to recalculate the minimum and maximum values and their positions, and then processing methods #1, #2, or #3 can be applied.

According to a processing method #5, a reading of the load variation on line 6 (illustrated e.g. in FIG. 1) combined with a simultaneous measurement of a single digital sensor 50 in conduit 8 and the ambient temperature can be used to calculate the thermal resistance between the digital sensor 50 in question and the surface of the corresponding cable 5 (R_{sensor-surface}) and the coefficient K according to

$$K = {K}_{T} ( \frac{di}{dT} )$$

where

$$( \frac{di}{dT} )$$

represents a derivative of the load with respect to a temperature measured by a digital sensor 50 and where the coefficient Kr can be evaluated, for example, by finite elements.

According to a processing method #6, a measurement of the load on line 6, performed in chamber 16 e.g. by acquisition unit 66 by means of coupler 64 or another current sensor (not shown), or elsewhere along line 6 and transmitted to remote site 74, combined with simultaneous measurements from two digital sensors 50 in conduit 8 and of the ambient temperature, can be used to recalculate the thermal resistances (R_{i-surface}) and coefficients Kᵢ.

According to a processing mode #7, the coefficient K recalculated according to methods #5 or #6 can be used to determine whether or not there is liquid present in conduit 8 (Kₐᵢᵣ vs K_{liquid}).

Referring again to FIG. 1, the invention may have various other features. For example, identification information for temperature probe 2 may be stored in temperature probe 2 and queried by acquisition unit 66. This information may include manufacturer information, model number, serial number, position of each digital sensor 50 in the conduit 8. This information may be stored in the digital sensors 50 (e.g., integrated non-volatile memory space), in the connector 108, and/or other elements of the temperature probe 2.

Although embodiments of the invention have been illustrated in the accompanying drawings and described above, it will be apparent to those skilled in the art that modifications may be made to these embodiments without departing from the invention. For example, although the invention has been described above in the context of an underground conduit, the invention can be used in a conduit that is not underground but has similar environmental characteristics. The invention can also be applied to an underground power distribution or transmission line. Furthermore, although the invention is particularly intended for measuring the temperature of an underground power line, it may also be used for other purposes. For example, as already mentioned above, the temperature probe may be used to measure temperatures at different depths in the ground or in a medium. Such use may serve to determine a frost line, in addition to dams and dikes, and to model soil characteristics to adjust finite element simulation software parameters. The invention may be used to measure the temperature of twisted electrical cables in a conduit in a building such as a factory.

According to certain aspects, embodiments of the present technology include the following items:

### [Item 1]

A temperature probe for measuring a temperature of twisted cables of a power line in operation in an underground conduit leaving only a restricted space between the twisted cables and an internal surface of the conduit, the temperature probe comprising:
an electrically insulating flexible tube, the flexible tube having first and second opposite ends and an outer diameter less than said limited space, the first end being adapted to be inserted into the conduit from an opening of the conduit to a depth within the conduit, the second end being adapted to remain accessible near the opening of the conduit when the first end is at said depth within the conduit;
an electrically insulating tapered tip sealingly attached to the first end of the flexible tube and configured to facilitate insertion of the flexible tube into the restricted space along the twisted cable in the conduit;
an array of digital temperature sensors housed and distributed longitudinally within the flexible tube, the number and distribution of the digital sensors being based on a linear spacing between two longitudinal peaks of the twisted cables; and
a connection assembly connecting the digital sensors, the connection assembly having a power supply circuit for supplying power to the digital sensors, and a communication circuit extending from the second end of the flexible tube for externally transmitting digital signals indicative of the temperatures measured by the digital sensors.

### [Item 2]

The temperature probe according to item 1, wherein the flexible tube and the tapered tip are made of materials that can withstand a temperature of at least 125° C. without changes in shape and physical properties.

### [Item 3]

The temperature probe according to item 2, wherein the materials are PVDF or PTFE.

### [Item 4]

The temperature probe according to any of items 1 to 3, wherein the tapered tip has a base with a diameter corresponding to the outer diameter of the flexible tube so that the tapered tip and the first end of the flexible tube have a smooth external interface when the tapered tip is in a sealing position with the first end of the flexible tube.

### [Item 5]

The temperature probe according to item 4, wherein the tapered tip has a rounded tip on a side opposite the base, and a parabolic circumference extending between the rounded tip and the base.

### [Item 6]

The temperature probe according to any of items 1 to 5, wherein the digital sensor array comprises printed circuit boards on which the digital sensors are respectively mounted and are operatively connected, the printed circuit boards having dimensions that allow clearance relative to an internal diameter of the flexible tube while supporting the digital sensors at or near an axial center of the flexible tube by contact with an internal surface of the flexible tube.

### [Item 7]

The temperature probe according to item 6, wherein the printed circuit boards comprise flexible printed circuit boards arranged end-to-end so as to form a continuous strip of printed circuits extending over a length exceeding a distance between a first and a last of the digital sensors.

### [Item 8]

The temperature probe according to item 7, wherein the power supply and communication circuits of the connection assembly comprise circuits formed on and interconnected between the flexible printed circuit boards.

### [Item 9]

The temperature probe according to item 6, wherein the power supply and communication circuits of the connection assembly comprise conductors extending between and connecting the printed circuit boards to each other.

### [Item 10]

A temperature probe according to any one of items 1 to 9, wherein the digital sensors are operatively connected in cascade to each other by the connection arrangement.

### [Item 11]

The temperature probe according to any of items 1 to 10, further comprising an outlet fitting sealed to the second end of the flexible tube, the power supply circuit and the communication circuit passing through the outlet fitting in a sealed manner.

### [Item 12]

The temperature probe according to any of items 1 to 11, wherein:
the flexible tube has a minimum length defined by a first section of the flexible tube corresponding to a depth in the conduit from which a temperature near the opening of the conduit no longer affects a temperature in the conduit, plus a second section of the flexible tube corresponding to one and a half times the linear distance;
the digital sensors are distributed throughout the second section of the flexible tube; and
the number and distribution of the digital sensors are defined by a spacing between each digital sensor in the second section of the flexible tube.

### [Item 13]

A system for remotely measuring the temperature of an accessible section of an electrical line in operation in an underground conduit, the remote measurement system comprising:
a temperature probe with digital sensors distributed in a flexible tube running along a length of the section of the power line in the underground conduit;
a power supply assembly connected to an electrical power source; and
an acquisition unit having an input connected to the power supply assembly for receiving electrical power, a connection port connected to the temperature probe for electrically powering the digital sensors and receiving digital temperature signals measured by the digital sensors, and a telecommunications device configured to transmit to a remote site of the underground conduit temperature measurement signals derived from the digital temperature signals received by the acquisition unit.

### [Item 14]

The system according to item 13, wherein the power supply assembly comprises a coupler configured to generate electrical power from the power line.

### [Item 15]

The system according to item 13 or 14, further comprising an ambient temperature sensor of an environment of the underground conduit, the ambient temperature sensor being connected to the acquisition unit, the acquisition unit being configured to transmit to the remote site, via the telecommunications device, a temperature measurement signal indicative of the ambient temperature measured by the ambient temperature sensor.

### [Item 16]

The system according to any of items 13 to 15, wherein the acquisition unit or temperature probe comprises a signal processing device configured to preprocess the digital temperature signals before transmission of the temperature measurement signals by the telecommunications device.

### [Item 17]

A method for measuring a temperature of an accessible section of an electrical line in operation in an underground conduit, the method comprising the steps of:
inserting a temperature probe with distributed digital sensors into a flexible tube such that the flexible tube runs along a length of the section of the electrical line in the underground conduit;
providing a power supply assembly connected to an electrical power source;
electrically powering the digital sensors of the temperature probe through an acquisition unit receiving electrical power from the power supply assembly;
receiving, via the acquisition unit, digital temperature signals measured by the digital sensors;
transmitting, via a telecommunications device, temperature measurement signals derived from the digital temperature signals received by the acquisition unit;
receiving, at a site remote from the underground conduit, the temperature measurement signals; and
processing, at the remote site, the digital temperature signals to determine a temperature of the electrical line based on at least one of the temperatures measured by the digital sensors, including the measured temperature that is the highest.

### [Item 18]

The method according to item 17, wherein the step of processing includes estimating a temperature T_{core} of a core of a cable of the power line, the estimate being determined by one of the following estimation methods:
a) T_{Core}=T_{Ambient}+K_{Surface} (T_{Surface}−T_{Ambient}) where T_{Ambient} is a temperature measured by a temperature sensor located in an environment adjacent to the underground conduit, and K_{Surface} is a predetermined coefficient of temperature variation T_{Core} of the cable core relative to a temperature T_{Surface} at a cable surface measured by one of the digital sensors;
b) T_{Core}=T_{Ambient}+K_{d} (T_{d}−T_{Ambient}) where K_{d} is a coefficient determined based on the twist geometry of the cable, and T_{d} is the difference between the highest temperature and the lowest temperature measured by the digital sensors;
c) estimation method b) in which K_{d} is corrected according to a deviation of the flexible tube of the temperature probe or the twisted cable, determined using two measurements of minimum or maximum temperatures, a reciprocal minimum or maximum temperature measured by the digital sensors, and a spacing between the digital sensors;
d) estimation method a), b) or c) in which minimum and maximum temperatures measured by the digital sensors are recalculated by interpolation of the temperatures measured by the digital sensors;
e) estimation method a), b), c) or d) in which the core temperature is corrected by determining a thermal resistance between at least one of the digital sensors and an external surface of the cable according to a load variation measured by a load sensor coupled to the power line; and
f) estimation method e) in which the thermal resistance and the coefficient K_{Surface} or K_{d} are determined according to the temperature T_{Ambient}.

### [Item 19]

The method according to item 17 or 18, further comprising the steps of:
coupling a load sensor to a cable of the power line to measure a load variation in the cable;
positioning a temperature sensor in a medium adjacent to the underground conduit to measure an ambient temperature of the medium;
determining a thermal coefficient between the temperature sensor and the cable based on the load variation and the ambient temperature; and
detecting the presence of a liquid in the underground conduit according to a value of the thermal coefficient.

### [Item 20]

The method according to any one of items 17 to 19, wherein readings of the digital temperature signals measured by the digital sensors are taken at fixed intervals or dynamically adjusted according to a variation in the electrical line load measured by a load sensor coupled to the electrical line.

What is claimed is:

1. A temperature probe for measuring a temperature of twisted cables of a power line in operation in an underground conduit leaving only a restricted space between the twisted cables and an internal surface of the conduit, the temperature probe comprising:
an electrically insulating flexible tube, the flexible tube having first and second opposite ends and an outer diameter less than said limited space, the first end being adapted to be inserted into the conduit from an opening of the conduit to a depth within the conduit, the second end being adapted to remain accessible near the opening of the conduit when the first end is at said depth within the conduit;
an electrically insulating tapered tip sealingly attached to the first end of the flexible tube and configured to facilitate insertion of the flexible tube into the restricted space along the twisted cable in the conduit;
an array of digital temperature sensors housed and distributed longitudinally within the flexible tube, the number and distribution of the digital sensors being based on a linear spacing between two longitudinal peaks of the twisted cables; and
a connection assembly connecting the digital sensors, the connection assembly having a power supply circuit for supplying power to the digital sensors, and a communication circuit extending from the second end of the flexible tube for externally transmitting digital signals indicative of the temperatures measured by the digital sensors.

2. The temperature probe according to claim 1, wherein the flexible tube and the tapered tip are made of materials that can withstand a temperature of at least 125° C. without changes in shape and physical properties.

3. The temperature probe according to claim 2, wherein the materials are PVDF or PTFE.

4. The temperature probe according to claim 1, wherein the tapered tip has a base with a diameter corresponding to the outer diameter of the flexible tube so that the tapered tip and the first end of the flexible tube have a smooth external interface when the tapered tip is in a sealing position with the first end of the flexible tube.

5. The temperature probe according to claim 4, wherein the tapered tip has a rounded tip on a side opposite the base, and a parabolic circumference extending between the rounded tip and the base.

6. The temperature probe according to claim 1, wherein the digital sensor array comprises printed circuit boards on which the digital sensors are respectively mounted and are operatively connected, the printed circuit boards having dimensions that allow clearance relative to an internal diameter of the flexible tube while supporting the digital sensors at or near an axial center of the flexible tube by contact with an internal surface of the flexible tube.

7. The temperature probe according to claim 6, wherein the printed circuit boards comprise flexible printed circuit boards arranged end-to-end so as to form a continuous strip of printed circuits extending over a length exceeding a distance between a first and a last of the digital sensors.

8. The temperature probe according to claim 7, wherein the power supply and communication circuits of the connection assembly comprise circuits formed on and interconnected between the flexible printed circuit boards.

9. The temperature probe according to claim 6, wherein the power supply and communication circuits of the connection assembly comprise conductors extending between and connecting the printed circuit boards to each other.

10. A temperature probe according to claim 1, wherein the digital sensors are operatively connected in cascade to each other by the connection arrangement.

11. The temperature probe according to claim 1, further comprising an outlet fitting sealed to the second end of the flexible tube, the power supply circuit and the communication circuit passing through the outlet fitting in a sealed manner.

12. The temperature probe according to claim 1, wherein:
the flexible tube has a minimum length defined by a first section of the flexible tube corresponding to a depth in the conduit from which a temperature near the opening of the conduit no longer affects a temperature in the conduit, plus a second section of the flexible tube corresponding to one and a half times the linear distance;
the digital sensors are distributed throughout the second section of the flexible tube; and
the number and distribution of the digital sensors are defined by a spacing between each digital sensor in the second section of the flexible tube.

13. A system for remotely measuring the temperature of an accessible section of an electrical line in operation in an underground conduit, the remote measurement system comprising:
a temperature probe with digital sensors distributed in a flexible tube running along a length of the section of the power line in the underground conduit;
a power supply assembly connected to an electrical power source; and
an acquisition unit having an input connected to the power supply assembly for receiving electrical power, a connection port connected to the temperature probe for electrically powering the digital sensors and receiving digital temperature signals measured by the digital sensors, and a telecommunications device configured to transmit to a remote site of the underground conduit temperature measurement signals derived from the digital temperature signals received by the acquisition unit.

14. The system according to claim 13, wherein the power supply assembly comprises a coupler configured to generate electrical power from the power line.

15. The system according to claim 13, further comprising an ambient temperature sensor of an environment of the underground conduit, the ambient temperature sensor being connected to the acquisition unit, the acquisition unit being configured to transmit to the remote site, via the telecommunications device, a temperature measurement signal indicative of the ambient temperature measured by the ambient temperature sensor.

16. The system according to claim 13, wherein the acquisition unit or temperature probe comprises a signal processing device configured to preprocess the digital temperature signals before transmission of the temperature measurement signals by the telecommunications device.

17. A method for measuring a temperature of an accessible section of an electrical line in operation in an underground conduit, the method comprising the steps of:
inserting a temperature probe with distributed digital sensors into a flexible tube such that the flexible tube runs along a length of the section of the electrical line in the underground conduit;
providing a power supply assembly connected to an electrical power source;
electrically powering the digital sensors of the temperature probe through an acquisition unit receiving electrical power from the power supply assembly;
receiving, via the acquisition unit, digital temperature signals measured by the digital sensors;
transmitting, via a telecommunications device, temperature measurement signals derived from the digital temperature signals received by the acquisition unit;
receiving, at a site remote from the underground conduit, the temperature measurement signals; and
processing, at the remote site, the digital temperature signals to determine a temperature of the electrical line based on at least one of the temperatures measured by the digital sensors, including the measured temperature that is the highest.

18. The method according to claim 17, wherein the step of processing includes estimating a temperature T_{core} of a core of a cable of the power line, the estimate being determined by one of the following estimation methods:
a) T_{Core}=T_{Ambient}+K_{Surface} (T_{Surface}−T_{Ambient}) where T_{Ambient} is a temperature measured by a temperature sensor located in an environment adjacent to the underground conduit, and K_{Surface} is a predetermined coefficient of temperature variation T_{Core} of the cable core relative to a temperature T_{Surface} at a cable surface measured by one of the digital sensors;
b) T_{Core}=T_{Ambient}+K_{d}(T_{d}−T_{Ambient}) where K_{d} is a coefficient determined based on the twist geometry of the cable, and T_{d} is the difference between the highest temperature and the lowest temperature measured by the digital sensors;
c) estimation method b) in which K_{d} is corrected according to a deviation of the flexible tube of the temperature probe or the twisted cable, determined using two measurements of minimum or maximum temperatures, a reciprocal minimum or maximum temperature measured by the digital sensors, and a spacing between the digital sensors;
d) estimation method a), b) or c) in which minimum and maximum temperatures measured by the digital sensors are recalculated by interpolation of the temperatures measured by the digital sensors;
e) estimation method a), b), c) or d) in which the core temperature is corrected by determining a thermal resistance between at least one of the digital sensors and an external surface of the cable according to a load variation measured by a load sensor coupled to the power line; and
f) estimation method e) in which the thermal resistance and the coefficient K_{Surface} or K_{d} are determined according to the temperature T_{Ambient}.

19. The method according to claim 17, further comprising the steps of:
coupling a load sensor to a cable of the power line to measure a load variation in the cable;
positioning a temperature sensor in a medium adjacent to the underground conduit to measure an ambient temperature of the medium;
determining a thermal coefficient between the temperature sensor and the cable based on the load variation and the ambient temperature; and
detecting the presence of a liquid in the underground conduit according to a value of the thermal coefficient.

20. The method according to claim 17, wherein readings of the digital temperature signals measured by the digital sensors are taken at fixed intervals or dynamically adjusted according to a variation in the electrical line load measured by a load sensor coupled to the electrical line.
